(19) United States
(12) Patent Application Publication
(10) Pub. No.: US 2021/0175054 A1
(43) Pub. Date: Jun. 10, 2021

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventor: Yasuhiko Kusama, Nagano-shi (JP)

(21) Appl. No.: 17/111,923

(22) Filed: Dec. 4, 2020

(30) Foreign Application Priority Data
Dec. 10, 2019 (JP) 2019-222739

(51) Int. Cl. H01J 37/32

(52) U.S. Cl. CPC H01J 37/32715; H01J 2237/334; H01J 2237/2007

(57) ABSTRACT

A positive electrode and a negative electrode face each other with a first gap around a gas hole, face each other with a first path and a second path with the gas hole being interposed therebetween, and face each other with a second gap around the gas hole. The first path and the second path converge to be the first gap at a first end, and converge to be the second gap at a second end. At the first end and the second end, corner portions formed by the positive electrode and the negative electrode are rounded. A first distance between the gas hole and the positive electrode is constant in the first path except the corner portions. A second distance between the gas hole and the negative electrode is constant in the second path except the corner portions. The first distance and the second distance are the same.

### CROSS-REFERENCE TO RELATED APPLICATIONS

Note that the present application is based on Japanese Patent Application No. 2019-222739 filed on Dec. 10, 2019, which is incorporated by reference in its entirety.

### TECHNICAL FIELD

The present invention relates to an electrostatic chuck, and a substrate fixing device.

### BACKGROUND ART

In the related art, a film formation apparatus and a plasma etching apparatus that are used when manufacturing a semiconductor device each have a stage for holding accurately a wafer in a vacuum treatment chamber. As the stage, for example, a substrate fixing device configured to suck and hold a wafer by an electrostatic chuck mounted on a base plate is suggested.

A substrate fixing device having a structure where a gas supply unit for cooling a wafer is provided may be exemplified. The gas supply unit supplies a gas to a surface of the electrostatic chuck through a gas flow path in the base plate and gas holes formed in the electrostatic chuck, for example (for example, refer to PTL 1).

### CITATION LIST

### Patent Literature

[PTL 1] JP-A-H07-45693

An electric discharge may occur around the gas holes of the electrostatic chuck. When the electric discharge occurs, there is a risk of burning or melting a rear surface of a suction target.

### SUMMARY OF INVENTION

Aspect of non-limiting embodiments of the present disclosure is to provide an electrostatic chuck capable of suppressing occurrence of an electric discharge around a gas hole.

An electrostatic chuck according to non-limiting embodiment of the present disclosure is an electrostatic chuck configured to suck and hold a suction target, comprising:

a base body on which the suction target is placed, the base body having a gas hole for supplying a gas to the suction target; and

a plurality of electrostatic electrodes embedded in the base body, the electrostatic electrodes comprising a positive electrode and a negative electrode,

wherein as seen from above, the positive electrode and the negative electrode are arranged to face each other with a first gap around the gas hole, the positive electrode and the negative electrode are arranged to face each other with a first path on the positive electrode-side and a second path on the negative electrode-side, the first path and the second path formed with the gas hole being interposed therebetween, and the positive electrode and the negative electrode are arranged to face each other with a second gap around the gas hole,

the first path and the second path extend along an outer periphery of the gas hole with the gas hole being interposed therebetween, converge to be the first gap at a first end, and converge to be the second gap at a second end,

wherein as seen from above, at a place at which the first path and the second path converge to be the first gap, a first corner portion formed by the positive electrode is rounded and a second corner portion formed by the negative electrode is rounded, and at a place at which the first path and the second path converge to be the second gap, a third corner portion formed by the positive electrode is rounded and a forth corner portion formed by the negative electrode is rounded, and

wherein as seen from above, a first distance between the gas hole and the positive electrode is constant in the first path except the rounded first and third corner portions, a second distance between the gas hole and the negative electrode is constant in the second path except the rounded second and fourth corner portions, and the first distance and the second distance are the same.

According to the disclosed technology, it is possible to provide the electrostatic chuck capable of suppressing occurrence of an electric discharge around the gas hole.

### BRIEF DESCRIPTION OF DRAWINGS

FIG. 1 is a simplified sectional view for depicting a substrate fixing device in accordance with a first embodiment.

FIG. 2 is a partially enlarged plan view of an A part in FIG. 1.

FIG. 3 illustrates distances between a positive electrode and a negative electrode of an electrostatic chuck and a gas hole in Comparative Example.

FIG. 4 illustrates a relation between a distance from a positive electrode or a negative electrode and a voltage.

FIG. 5 is a simplified sectional view for depicting a substrate fixing device in accordance with a second embodiment.

FIG. 6 is a partially enlarged sectional view of a B part in FIG. 5.

FIG. 7 is a partially enlarged sectional view of the B part in FIG. 5.

### DESCRIPTION OF EMBODIMENTS

Hereinbelow, embodiments of the present invention will be described with reference to the drawings. In the respective drawings, the same constitutional parts are denoted with the same reference signs, and overlapping descriptions may be omitted.

### First Embodiment

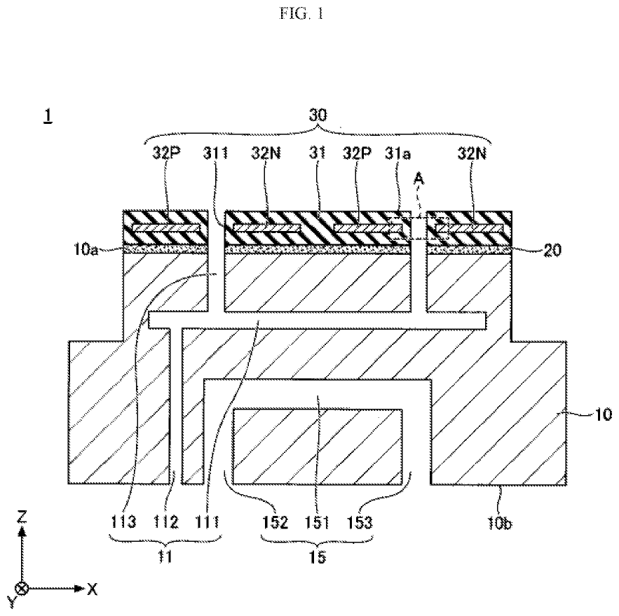

FIG. 1 is a simplified sectional view for depicting a substrate fixing device in accordance with a first embodiment. Referring to FIG. 1, a substrate fixing device 1 includes, as main constitutional elements, a base plate 10, an adhesion layer 20, and an electrostatic chuck 30. The substrate fixing device 1 is a device configured to suck and hold a substrate (a wafer and the like), which is a suction target, by the electrostatic chuck 30 mounted on one surface of the base plate 10.

The base plate 10 is a member for mounting the electrostatic chuck 30. A thickness of the base plate 10 is, for example, about 20 mm to 40 mm. The base plate 10 is formed of, for example, aluminum, and can be used as an electrode for controlling plasma. By supplying predetermined high-frequency electric power to the base plate 10, it is possible to control energy for causing ions in a generated plasma state to collide with the substrate sucked on the electrostatic chuck 30, and to effectively perform an etching treatment.

In the base plate 10, a gas supply unit 11 is provided. The gas supply unit 11 has a gas flow path 111, a gas injection part 112, and gas discharge parts 113.

The gas flow path 111 is an annular hole formed in the base plate 10, for example. The gas injection part 112 is a hole having one end communicating with the gas flow path 111 and the other end exposed to an outside from a lower surface 10b of the base plate 10, and is provided to introduce an inert gas (for example, He, Ar and the like) for cooling the substrate sucked on the electrostatic chuck 30, from an outside of the substrate fixing device 1. The gas discharge part 113 is a hole having one end communicating with the gas flow path 111 and the other end exposed to an outside from an upper surface 10a of the base plate 10 and penetrating the adhesion layer 20, and is provided to discharge the inert gas introduced into the gas flow path 111. As seen from above, the gas discharge parts 113 are scattered on the upper surface 10a of the base plate 10. The number of the gas discharge parts 113 can be determined as appropriate, as necessary, and is, for example, about several tens to several hundreds.

In the meantime, the description “as seen from above” means that a target is seen in a normal direction of the upper surface 10a of the base plate 10, and a planar shape indicates a shape seen in the normal direction of the upper surface 10a of the base plate 10.

In the base plate 10, a cooling mechanism 15 may also be provided. The cooling mechanism 15 has a coolant flow path 151, a coolant introduction part 152, and a coolant discharge part 153. The coolant flow path 151 is an annular hole formed in the base plate 10, for example. The coolant introduction part 152 is a hole having one end communicating with the coolant flow path 151 and the other end exposed to the outside from the lower surface 10b of the base plate 10, and is provided to introduce a coolant (for example, cooling water, GALDEN and the like) from the outside of the substrate fixing device 1 into the coolant flow path 151. The coolant discharge part 153 is a hole having one end communicating with the coolant flow path 151 and the other end exposed to the outside from the lower surface 10b of the base plate 10, and is provided to discharge the coolant introduced into the coolant flow path 151.

The cooling mechanism 15 is connected to a coolant control device (not shown) provided outside of the substrate fixing device 1. The coolant control device (not shown) is configured to introduce the coolant from the coolant introduction part 152 into the coolant flow path 151, and to discharge the coolant from the coolant discharge part 153. The coolant is caused to circulate in the cooling mechanism 15 to cool the base plate 10, so that it is possible to cool the wafer sucked on the electrostatic chuck 30.

The electrostatic chuck 30 is a part for sucking and holding the wafer that is a suction target. A planar shape of the electrostatic chuck 30 is, for example, circular. A diameter of the wafer that is a suction target of the electrostatic chuck 30 is, for example, 8 inches, 12 inches, or 18 inches.

The electrostatic chuck 30 is provided on the upper surface 10a of the base plate 10 with the adhesion layer 20 being interposed therebetween. The adhesion layer 20 is, for example, a silicon-based adhesive. A thickness of the adhesion layer 20 is, for example, about 0.1 mm to 1.0 mm. The adhesion layer 20 bonds the base plate 10 and the electrostatic chuck 30 each other, and has an effect of reducing stress that is generated due to a difference in thermal expansion coefficient between the ceramic electrostatic chuck 30 and the aluminum base plate 10.

The electrostatic chuck 30 has a base body 31, positive electrodes 32P and negative electrodes 32N. An upper surface of the base body 31 is a placement surface 31a for a suction target. The electrostatic chuck 30 is, for example, a Johnson-Rahbek type electrostatic chuck. However, the electrostatic chuck 30 may also be a Coulomb force type electrostatic chuck.

The base body 31 is a dielectric body. As the base body 31, for example, a ceramic such as aluminum oxide (Al₂O₃) and aluminum nitride (AlN) is used. A thickness of the base body 31 is, for example, about 1 mm to 5 mm, and a specific permittivity (1 kHz) of the base body 31 is, for example, about 9 to 10.

The positive electrodes 32P and the negative electrodes 32N are bipolar electrostatic electrodes formed of thin films, and are embedded in the base body 31. The positive electrodes 32P and the negative electrodes 32N are formed in a comb teeth-shaped electrode pattern, for example, and teeth of each electrode are alternately arranged at predetermined intervals. The positive electrodes 32P and the negative electrodes 32N are connected to a power supply provided outside of the substrate fixing device 1, and generate a suction force by static electricity between the electrodes and the wafer when a predetermined voltage is applied from the power supply. Thereby, the wafer can be sucked and held on the placement surface 31a of the base body 31 of the electrostatic chuck 30. When a higher voltage is applied between the positive electrode 32P and the negative electrode 32N, a suction holding force becomes stronger. As materials of the positive electrode 32P and the negative electrode 32N, tungsten, molybdenum and the like are used, for example.

In the base body 31, a heating element (heater) that generates heat when a voltage is applied from the outside of the substrate fixing device 1 and heats the placement surface 31a of the base body 31 to a predetermined temperature may also be provided.

Gas holes 311 formed to penetrate the base body 31 and to expose the other ends of the gas discharge parts 113 are provided in positions corresponding to the gas discharge parts 113 of the base body 31. A planar shape of the gas hole 311 is, for example, a circular shape having an inner diameter of about 0.1 mm to 1 mm. The gas holes 311 can be formed by drilling or laser processing, for example. The inert gas is supplied to a rear surface of the suction target sucked on the electrostatic chuck 30 through the gas holes 311, so that the suction target is cooled.

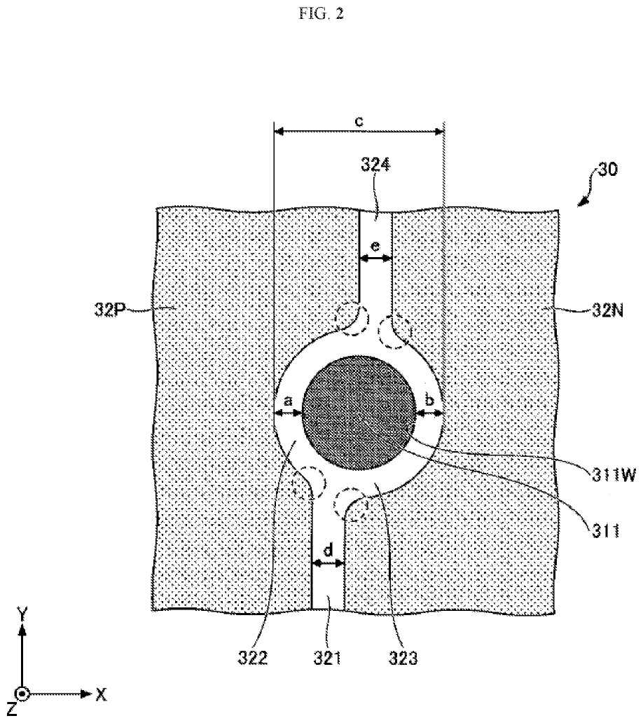

FIG. 2 is a partially enlarged plan view of an A part in FIG. 1, depicting distances between the positive electrode 32P and the negative electrode 32N and the gas hole 311 around the gas hole 311. In FIG. 2, the base body 31 is not shown. In FIG. 2, a thickness direction of the electrostatic chuck 30 is denoted as a Z direction, a direction in which a gap separating the positive electrode 32P and the negative electrode 32N in a plane perpendicular to the Z direction extends is denoted as a Y direction, and a direction orthogonal to the Y direction in the plane perpendicular to the Z direction is denoted as an X direction (width direction).

As shown in FIG. 2, the positive electrode 32P and the negative electrode 32N are patterned at predetermined distances from the gas hole 311 so as not to contact the gas hole 311, around the gas hole 311.

Specifically, as seen from above, the positive electrode 32P and the negative electrode 32N are arranged to face each other with a first gap 321 on a −(negative)Y-side of the gas hole 311 around the gas hole 311. The first gap 321 is divided into a first path 322 on the positive electrode 32P-side and a second path 323 on the negative electrode 32N-side at the gas hole 311. The positive electrode 32P and the negative electrode 32N are arranged to face each other with the first path 322 and the second path 323 between which the gas hole 311 is interposed. The first path 322 and the second path 323 extend along an outer periphery of the gas hole 311 with the gas hole 311 being interposed therebetween, and converge to be one second gap 324 on a +(positive)Y-side of the gas hole 311. The positive electrode 32P and the negative electrode 32N are arranged to face each other with the second gap 324 on the −(negative)Y-side of the gas hole 311 around the gas hole 311. The first path 322 and the second path 323 extend along an outer periphery of the gas hole 311, and converge to be the first gap 321 at a first end on the −Y-side of the gas hole 311 and converge to be the second gap 324 at a second end on the +Y-side of the gas hole 311.

As used herein, the gap means that the targets are arranged spaced, and does not mean that there is a space in the gap (no material exists in the gap). In the first gap 321, the first path 322, the second path 323 and the second gap 324, the base body 31 is arranged.

As seen from above, at a place at which the first gap 321 is divided into the first path 322 and the second path 323 (in other words, at a place at which the first path 322 and the second path 323 are converged to be the first gap 321) and at a place at which the first path 322 and the second path 323 are converged to be the second gap 324, corner portions formed by the positive electrode 32P and corner portions formed by the negative electrode 32N are not sharpened but rounded (four places in circles of broken lines). The rounded corner portion preferably has R=0.1 μm or larger.

As seen from above, a first distance a between the gas hole 311 and the positive electrode 32P is constant in the first path 322 except the rounded corner portions. Also, a second distance b between the gas hole 311 and the negative electrode 32N is constant in the second path 323 except the rounded corner portions. The first distance a and the second distance b are the same. Here, the distance between the gas hole 311 and the positive electrode 32P or the negative electrode 32N is a distance in a normal direction of a tangent line at each point of an inner wall 311W of the gas hole 311, as seen from above.

Also, a maximum distance in the X direction between the positive electrode 32P and the negative electrode 32N around the gas hole 311 is a distance c, as seen from above.

A third distance d in a width direction (X direction) of the first gap 321 between the positive electrode 32P and the negative electrode 32N is preferably the same as a fourth distance e in the width direction (X direction) of the second gap 324 between the positive electrode 32P and the negative electrode 32N. More preferably, the first distance a, the second distance b, the third distance d and the fourth distance e are all the same. The first distance a, the second distance b, the third distance d, and the fourth distance e are arbitrarily set within a range of about 0.1 mm to 10 mm, for example.

Here, effects achieved by the electrostatic chuck 30 are described with reference to Comparative Example.

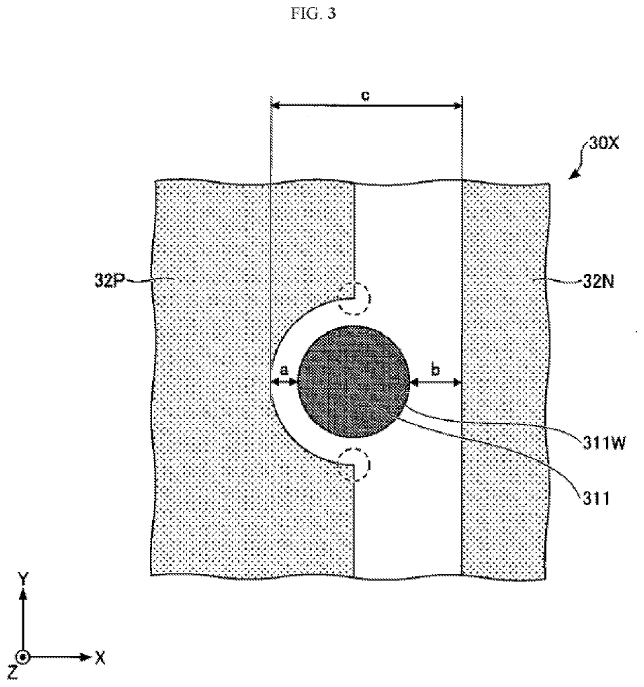

FIG. 3 illustrates distances between a positive electrode and a negative electrode of an electrostatic chuck and a gas hole in Comparative Example, and is a partially enlarged plan view corresponding to FIG. 2. In FIG. 3, the base body 31 is not shown.

An electrostatic chuck 30X in accordance with Comparative Example shown in FIG. 3 is different from the electrostatic chuck 30 shown in FIG. 2, in that an end portion of the negative electrode 32N facing the positive electrode 32P with the gas hole 311 being interposed therebetween is linear in the Y direction, as seen from above. Also, as seen from above, corner portions formed by the positive electrode 32P are not rounded but sharpened (two places in circles of broken lines), which is different from the electrostatic chuck 30 shown in FIG. 2.

In the electrostatic chuck 30X, the first distance a between the gas hole 311 and the positive electrode 32P is constant on a −X-side from a center of the gas hole 311. However, since the negative electrode 32N has a shape as described above, the second distance b between the gas hole 311 and the negative electrode 32N is not constant on a +X-side from the center of the gas hole 311. Therefore, a relation of the first distance a and the second distance b (the first distance a is equal to the second distance b) is not made.

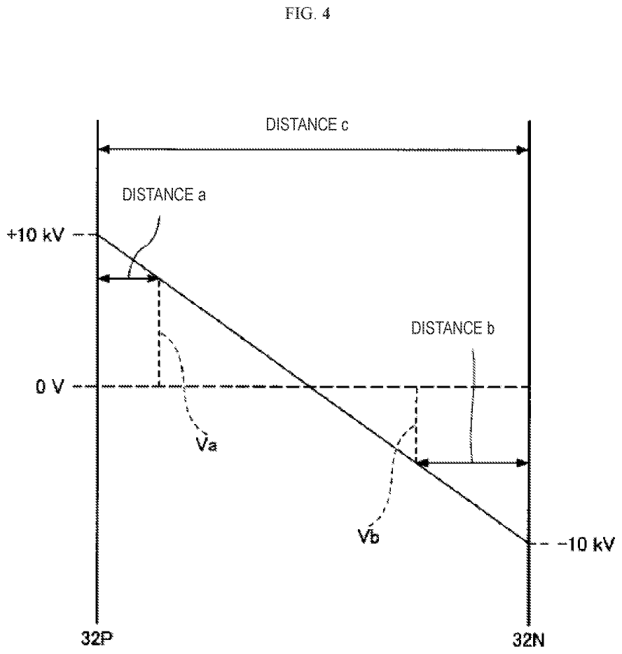

For example, in a case where the first distance a and the second distance b are not the same (it is assumed that a<b) at the position shown in FIG. 3, it is assumed that a DC voltage of +10 kV is applied to the positive electrode 32P and a DC voltage of −10 kV is applied to the negative electrode 32N. In this case, as shown in FIG. 4, a voltage Va at the gas hole 311 located at a position of the distance a from the positive electrode 32P is higher than a voltage Vb at the gas hole 311 located at a position of the distance b from the negative electrode 32N. In this case, the voltage is biased to a plus side, so that positive charges are likely to be accumulated. When the positive charges are accumulated to some extent or more, an electric discharge occurs. The electric discharge may also be referred to a dielectric barrier electric discharge. In the meantime, even when the voltage is biased to a minus side, the charges are unevenly distributed, so that the electric discharge occurs.

Even if the first distance a and the second distance b are made to be the same at the position shown in FIG. 3, no countermeasure against the electric discharge is provided. This is because the second distance b between the gas hole 311 and the negative electrode 32N is not constant on the +X-side from the center of the gas hole 311, as described above. That is, in the shape of FIG. 3, since a part where the first distance a is not the same as the second distance b always exists around the gas hole 311, the electric discharge as described above occurs. When the electric discharge as described above occurs, there is a risk of burning or melting a rear surface of the substrate that is a suction target. For this reason, it is required to suppress the electric discharge as described above.

Therefore, in the electrostatic chuck 30, the corner portions formed by the positive electrode 32P and the negative electrode 32N are rounded, and the first distance a and the second distance b are made to be the same, as seen from above, except the rounded corner portions. That is, in the electrostatic chuck 30, since the first distance a is the same as the second distance b over the substantially entire region on the outer periphery-side of the gas hole 311, the voltage Va and the voltage Vb described with respect to FIG. 4 are the same, so that charges are not unevenly distributed.

As a result, it is possible to suppress occurrence of the electric discharge.

Also, the electric discharge is more likely to occur at an acuter portion. However, in the electrostatic chuck 30, the corner portions formed by the positive electrode 32P and the negative electrode 32N are rounded, so that it is also possible suppress occurrence of the electric discharge. The rounded corner portion having R of 0.1 μm or greater can contribute to suppression of occurrence of the electric discharge.

Also, it is preferably that the third distance d is the same as the fourth distance e. Thereby, the charges are not unevenly distributed even in a region slightly distant from the gas hole 311, so that it is possible to further suppress occurrence of the electric discharge.

Also, it is more preferably that the first distance a, the second distance b, the third distance d and the fourth distance e are all the same. The third distance d and the fourth distance e are made to be the same as the first distance a and the second distance b, so that the distances from each of the positive electrode 32P and the negative electrode 32N are the same and charge amounts in each position are the same. For this reason, for example, when stopping the applying of the voltage to the positive electrode 32P and the negative electrode 32N and demounting the wafer from the electrostatic chuck, the loss of charges is the same, so that it is possible to suppress the wafer from being positionally misaligned.

### Second Embodiment

In a second embodiment, an example where a porous body is arranged in the gas hole is described. In the second embodiment, the descriptions of the same constitutional parts as the above-described embodiment may be omitted.

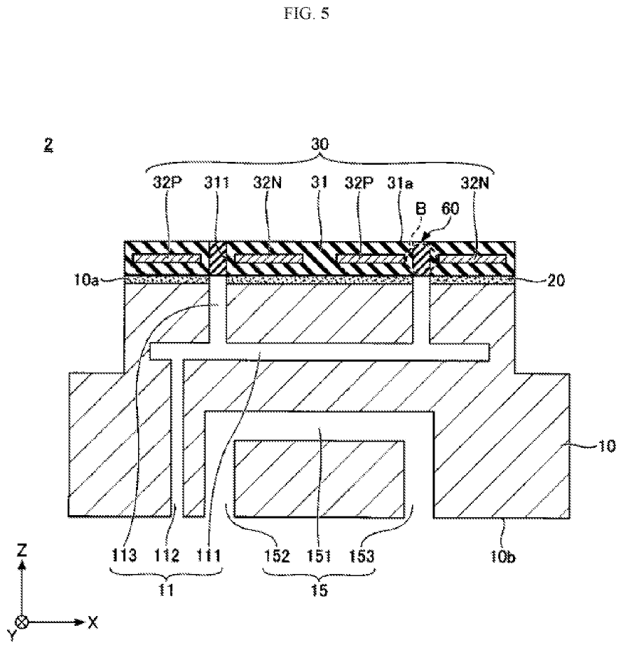

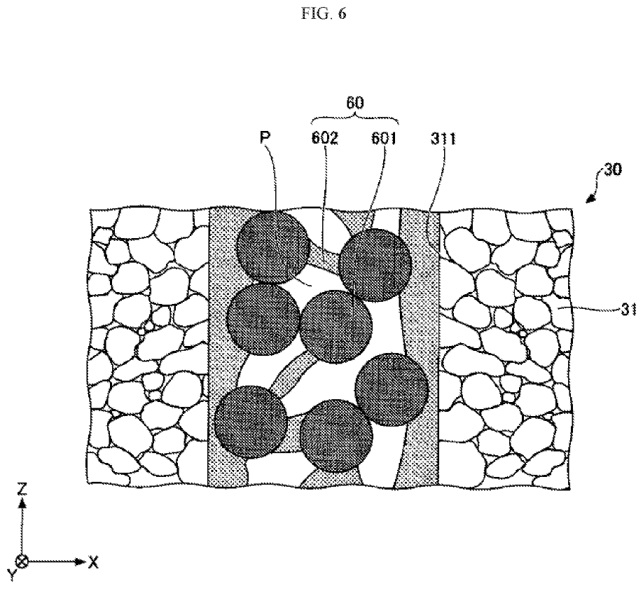

FIG. 5 is a simplified sectional view for depicting a substrate fixing device in accordance with a second embodiment. FIG. 6 is a partially enlarged sectional view of a B part in FIG. 5. Referring to FIGS. 5 and 6, a substrate fixing device 2 is different from the electrostatic chuck 30 (refer to FIG. 1 and the like), in that a porous body 60 is arranged in the gas hole 311.

The porous body 60 includes a plurality of spherical oxide ceramic particles 601, and a mixed oxide 602 that binds and integrates the plurality of spherical oxide ceramic particles 601.

A diameter of the spherical oxide ceramic particle 601 is, for example, within a range of 30 μm to 1000 μm. As a favorable example of the spherical oxide ceramic particle 601, a spherical aluminum oxide particle may be exemplified. Also, the spherical oxide ceramic particles 601 are preferably contained in a weight ratio of 80 wt % or more (and 97 wt % or less) in the porous body 60.

The mixed oxide 602 adheres to some of outer surfaces (spherical surfaces) of the plurality of spherical oxide ceramic particles 601 and supports the same. The mixed oxide 602 is formed of oxides of two or more elements selected from silicon (Si), magnesium (Mg), calcium (Ca), aluminum (Al) and yttrium (Yt), for example.

In the porous body 60, pores P are formed. The pores P communicate with the outside so as to cause the gas to pass through from a lower side toward an upper side of the porous body 60. A porosity of the pores P formed in the porous body 60 is preferably within a range of 20% to 50% of an entire volume of the porous body 60. To inner surfaces of the pores P, some of the outer surfaces of the spherical oxide ceramic particles 601 and the mixed oxide 602 are exposed.

When the base body 31 is formed of aluminum oxide, the base body 31 preferably contains, as other components, oxides of two or more elements selected from silicon, magnesium, calcium and yttrium. A composition ratio of oxides of two or more elements selected from silicon, magnesium, calcium and yttrium in the base body 31 is preferably set to be the same as a composition ratio of oxides of two or more elements selected from silicon, magnesium, calcium and yttrium in the mixed oxide 602 of the porous body 60.

In this way, the composition ratios of oxides are made to be the same between the base body 31 and the mixed oxide 602 of the porous body 60, so that mutual material transfer does not occur when sintering the porous body 60. Therefore, it is possible to secure flatness of an interface between the base body 31 and the porous body 60.

The porous body 60 can be formed by charging paste, which is a precursor of the porous body 60, in the gas hole 311 by using a squeegee or the like and sintering the same. When a part of the porous body 60 protrudes from a lower surface-side of the base body 31, grinding or the like is preferably performed so that an end face of the porous body 60 is substantially flush with the lower surface of the base body 31.

The paste that is a precursor of the porous body 60 contains, for example, spherical aluminum oxide particles in a predetermined weight ratio. The rest of the paste contains oxides of two or more elements selected from silicon, magnesium, calcium, aluminum and yttrium, for example, and further contains an organic binder and a solvent. As the organic binder, for example, polyvinyl butyral may be used. As the solvent, for example, alcohol may be used.

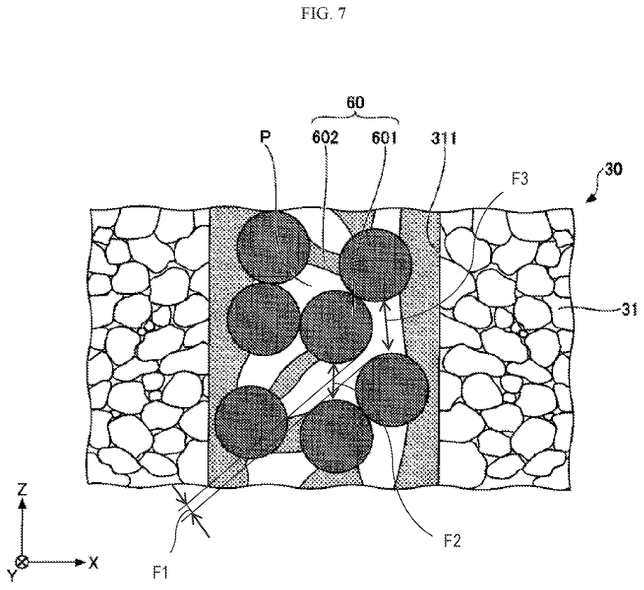

As described above, the porous body 60 may be arranged in the gas hole 311. Since the porous body 60 is also a dielectric body, charges are accumulated. Since the porous body 60 has the pores P, the electric discharge may occur at a short distance. In the process of arranging the porous body 60 in the gas hole 311, it is difficult to control the size of the pores P and the size of the mixed oxide 602. Therefore, as shown in FIG. 7, distances (for example, F1, F2, F3) between the adjacent the spherical oxide ceramic particles 601 are not constant, and thus discharge may occur at the shorter distance (for example, F2) in these distances.

Therefore, similar to the first embodiment, the corner potions formed by the positive electrode 32P and the negative electrode 32N are rounded, and the first distance a and the second distance b are made to be the same, as seen from above, except the rounded corner portions. Thereby, charges are not unevenly distributed, so that occurrence of the electric discharge can be suppressed.

Also, the corner potions formed by the positive electrode 32P and the negative electrode 32N are preferably rounded, the third distance d is more preferably the same as the fourth distance e, and further preferably, the first distance a, the second distance b, the third distance d and the fourth distance e are all the same.

Although the preferred embodiments have been described in detail, the present invention is not limited to the above embodiments and the above embodiments can be diversely modified and replaced without departing from the scope of the claims.

For example, as the suction target of the substrate fixing device of the present invention, a glass substrate and the like that are used in a manufacturing process of a liquid crystal panel and the like may be exemplified, in addition to the semiconductor wafer (silicon wafer, and the like).

What is claimed is:

1. An electrostatic chuck configured to suck and hold a suction target, comprising:
a base body on which the suction target is placed, the base body having a gas hole for supplying a gas to the suction target; and
a plurality of electrostatic electrodes embedded in the base body, the electrostatic electrodes comprising a positive electrode and a negative electrode,
wherein as seen from above, the positive electrode and the negative electrode are arranged to face each other with a first gap around the gas hole, the positive electrode and the negative electrode are arranged to face each other with a first path on the positive electrode-side and a second path on the negative electrode-side, the first path and the second path formed with the gas hole being interposed therebetween, and the positive electrode and the negative electrode are arranged to face each other with a second gap around the gas hole, the first path and the second path extend along an outer periphery of the gas hole with the gas hole being interposed therebetween, converge to be the first gap at a first end, and converge to be the second gap at a second end,
wherein as seen from above, at a place at which the first path and the second path converge to be the first gap, a first corner portion formed by the positive electrode is rounded and a second corner portion formed by the negative electrode is rounded, and at a place at which the first path and the second path converge to be the second gap, a third corner portion formed by the positive electrode is rounded and a forth corner portion formed by the negative electrode is rounded, and
wherein as seen from above, a first distance between the gas hole and the positive electrode is constant in the first path except the rounded first and third corner portions, a second distance between the gas hole and the negative electrode is constant in the second path except the rounded second and fourth corner portions, and the first distance and the second distance are the same.

2. The electrostatic chuck according to claim 1, wherein as seen from above, a third distance between the positive electrode and the negative electrode in a width direction of the first gap is the same as a fourth distance between the positive electrode and the negative electrode in a width direction of the second gap.

3. The electrostatic chuck according to claim 2, wherein the first distance, the second distance, the third distance and the fourth distance are all the same.

4. The electrostatic chuck according to claim 1, further comprising:
a porous body arranged in the gas hole, the porous body having a plurality of pores communicating with each other.

5. The electrostatic chuck according to claim 4, wherein the porous body comprises spherical oxide ceramic particles, and a mixed oxide binding the spherical oxide ceramic particles.

6. A substrate fixing device comprising:
a base plate; and
the electrostatic chuck according to claim 1 mounted on one surface of the base plate.
